(19) United States
(12) Patent Application Publication
(10) Pub. No.: US 2010/0078646 A1
(43) Pub. Date: Apr. 1, 2010

(54) DISPLAY DEVICE

(75) Inventors: Shiro SUMITA, Ishikawa-ken (JP); Motonobu AOKI, Ishikawa-ken (JP); Tetsuo ISHIDA, Ishikawa-ken (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Toshiba Mobile Display Co., Ltd., Minato-ku (JP)

(21) Appl. No.: 12/489,513

(22) Filed: Jun. 23, 2009

(30) Foreign Application Priority Data
Sep. 26, 2008 (JP) 2008-249090

(51) Int. Cl. H01L 33/00

(52) U.S. Cl. 257/72; 257/E33.003

(57) ABSTRACT

A display device including an active area having a plurality of pixels comprises an array substrate including a plurality of display elements disposed at said pixels respectively; a sealing substrate disposed to be opposed to said array substrate; and a seal member disposed between said array substrate and said sealing substrate and encircling said active area; wherein said seal member is made of frit glass, and a resin layer is disposed between said array substrate and said sealing substrate in said active area.

### CROSS-REFERENCE TO RELATED APPLICATIONS

This application is based upon and claims the benefit of priority from the prior Japanese Patent Application No. 2008-249090, filed Sep. 26, 2008, the entire contents of which are incorporated herein by reference.

### BACKGROUND OF THE INVENTION

1. Field of the Invention

The present invention relates generally to a display device, and more particularly to a display device including a self-luminous display element.

2. Description of the Related Art

In recent years, attention has been paid to an organic electroluminescence (EL) display device as a flat-panel display device. Since the organic EL display device includes self-luminous display elements, the organic EL display device has such features that the viewing angle is wide, no backlight is needed and thus reduction in thickness can be achieved, power consumption can be decreased, and high responsivity is obtained.

By virtue of these features, attention has been paid to the organic EL display device as a promising candidate for the next-generation flat-panel display device that is to replace the liquid crystal display devices. The organic EL display device includes an organic EL element in which an organic active layer having a light emission function is held between an anode and a cathode.

The organic EL display devices are classified into a bottom emission type in which EL light that is generated from the organic EL element is extracted to the outside from an array substrate side, and a top emission type in which EL light that is generated from the organic EL element is extracted to the outside from a sealing substrate side.

The organic EL element includes a thin film which easily deteriorates due to the effect of moisture or oxygen. Therefore, the EL element is needed to be sealed so as not to be exposed to the atmosphere.

There has been proposed a structure wherein a array substrate including the organic EL element and a sealing substrate are bonded each other via a sealant made of frit glass which is disposed at the peripheral area of these substrates. With this structure, no moisture-absorbing material is needed on the inner surface of the sealing substrate because the moisture is blocked to enter into the gap between the array substrate and the sealing substrate. Therefore, this structure can be used for the top emission type (see, e.g. Jpn. Pat. Appln. KOKAI Publication No. 2007-200840).

However, in case a small gap is formed between the array substrate and the sealing substrate which seal the organic EL element, a display quality may be decreased because a moiré stripe tend to be generated on the display by the optical interference.

To avoid generating the moiré stripe, there is a resort to increasing the gap used by a sealing substrate with a concave in its inner surface. However, in the above described resort, the cost for manufacturing the display device may increase because a special process such as etching process is needed to make the concave. Moreover, in this structure, the mechanical strength may not be sufficient, especially when the panel size is large, because of the thinness in the concave portion of the sealing substrate.

### BRIEF SUMMARY OF THE INVENTION

The present invention has been made in consideration of the above-described problems, and the object of the invention is to provide a display device wherein the generation of the moiré stripe can be suppressed, good display quality can be achieved, the thickness can be thinner and the display size can be larger with maintenance of the necessary mechanical strength.

According to a first aspect of the present invention, there is provided a display device including an active area having a plurality of pixels comprising: an array substrate including a plurality of display elements disposed at said pixels respectively; a sealing substrate disposed to be opposed to said array substrate; and a seal member disposed between said array substrate and said sealing substrate and encircling said active area; wherein said seal member is made of frit glass, and a resin layer is disposed between said array substrate and said sealing substrate in said active area.

The present invention can provide a display device, wherein the generation of the moiré stripe can be suppressed, good display quality can be achieved, the thickness can be thinner and the display size can be larger with maintenance of the necessary mechanical strength.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the preferred embodiments given below, serve to explain the principles of the invention.

FIG. 1 schematically shows the structure of an organic EL display device according to an embodiment of the present invention;

FIG. 2 is a cross-sectional view that schematically shows a cross-sectional structure of the organic EL display device shown in FIG. 1;

FIG. 3 is a cross-sectional view that schematically shows a example of the structure of the organic EL display device according to the embodiment;

FIG. 4 is a cross-sectional view that schematically shows an another example of the structure of the organic EL display device according to the embodiment;

FIG. 5 is a plan view that schematically shows the example of the structure of the organic EL display device shown in FIG. 4; and

FIG. 6 shows a verification result of the effectiveness of a resin layer.

### DETAILED DESCRIPTION OF THE INVENTION

A display device according to an embodiment of the present invention will now be described with reference to the accompanying drawings. In this embodiment, a self-luminous display device, such as an organic EL (electroluminescence) display device, is described as an example of the display device.

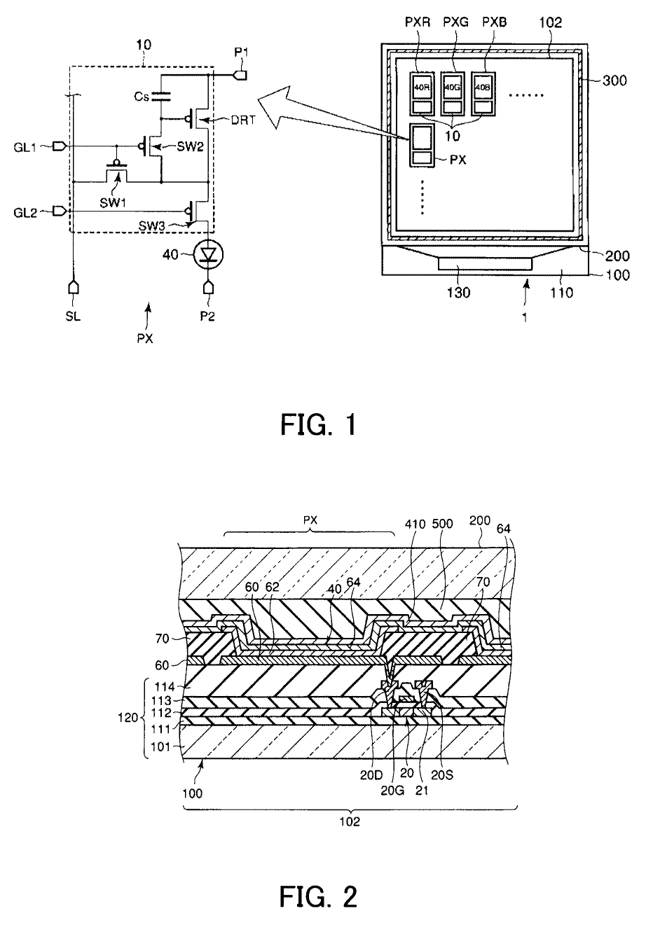

As is shown in FIG. 1, an organic EL display device 1 includes an array substrate 100 with an active area 102 for displaying an image. The active area 102 is composed of a plurality of pixels PX which arrayed in a matrix. FIG. 1 shows the organic EL display device 1 of a color display type, by way of example, and the active area 102 is composed of a plurality of kinds of color pixels, for instance, a red pixel PXR, a green pixel PXG and a blue pixel PXB corresponding to the three primary colors.

At least the active area 102 of the array substrate 100 is sealed by a sealing substrate 200. The sealing substrate 200 is made of a transparent and an insulating material (especially glass). Inner surface of the sealing substrate 200 which is opposed to the array substrate 100 is flat.

The array substrate 100 and the sealing substrate 200 are bonded each other via a seal member 300 which is a frame shape and is disposed around the active area 102. In this embodiment, the seal member 300 is made of frit glass.

Each of the pixels PX (R, G, B) includes a pixel circuit 10 and a display element 40 which is driven and controlled by the pixel circuit 10. Needless to say, the pixel circuit 10 shown in FIG. 1 is merely an example, and pixel circuits with other structures are applicable.

In the example shown in FIG. 1, the pixel circuit 10 is configured to include a driving transistor DRT, various switches (a first switch SW1, a second switch SW2 and third switch SW3) and a storage capacitance element Cs. The driving transistor DRT has a function of controlling the amount of electric current that is supplied to the display element 40. The first switch SW1 and the second switch SW2 function as a sample/hold switch. The third switch SW3 has a function of controlling the supply of driving current from the driving transistor DRT to the display element 40, that is, the turning on/off of the display element 40. The storage capacitance Cs has a function of retaining a gate-source potential of the driving transistor DRT.

The driving transistor DRT is connected between a high-potential power supply line P1 and the third switch SW3. The display element 40 is connected between the third switch SW3 and a low-potential power supply line P2. The gate electrodes of the first switch SW1 and second switch SW2 are connected to a first gate line GL1. The gate electrode of the third switch SW3 is connected to a second gate line GL2. The source electrode of the first switch SW1 is connected to a video signal line SL.

The driving transistor DRT, first switch SW1, second switch SW2 and third switch SW3 are composed of, for example, thin-film transistors, and their semiconductor layers are formed of polysilicon (polycrystalline silicon) in this example.

In this case of this circuit structure, the first switch SW1 and second switch SW2 are turned on, on the basis of the supply of an ON signal from the first gate line GL1. An electric current flows from the high-potential power supply line P1 to the driving transistor DRT in accordance with the amount of electric current flowing in the video signal line SL, and the storage capacitance element Cs is charged in accordance with the electric current flowing in the driving transistor DRT. Thereby, the driving transistor DRT can supply the same amount of electric current as the one of which is supplied from the video signal line SL from the high-potential power supply line P1 to the display element 40.

On the basis of the supply of the ON signal from the second gate line GL2, the third switch SW3 is turned on, and the driving transistor DRT supplies a predetermined amount of current corresponding to a predetermined luminance from the high-potential power supply line P1 to the display element 40 via the third switch SW3 in accordance with the capacitance that is retained in the storage capacitance element Cs. Thereby, the display element 40 emits light with a predetermined luminance.

The display element 40 is composed of the organic EL element 40 (R, G, B). Specifically, the red pixel PXR includes an organic EL element 40R which mainly emits light corresponding to a red wavelength. The green pixel PXG includes an organic EL element 40G which mainly emits light corresponding to a green wavelength. The blue pixel PXB includes an organic EL element 40B which mainly emits light corresponding to a blue wave length.

The respective kinds of organic EL elements 40 (R, G, B) have basically the same structure. For example, as shown in FIG. 2, the array substrate 100 includes a plurality of organic EL elements 40 which are disposed on the major surface side of a wiring substrate 120. The wiring substrate 120 is configured such that insulation layers, such as an under coat layer 111, a gate insulation film 112, an interlayer insulation film 113 and protection film 114, and various switches SW, driving transistor DRT, storage capacitance element Cs and various wiring lines (gate lines, video lines, power supply lines, ect.), are provided on an insulating support substrate 101 such as a glass substrate. The under coat layer 111, gate insulation film 112 and interlayer insulation film 113 are made of inorganic materials such as silicon nitride (SiNx) and silicon oxide (SiO2).

The protection film 114 may be made of an organic material or an inorganic material such as silicon nitride. In case of the protection film 114 made of an organic material, it can absorb the roughness of the surface of the under layer and planarize it.

Specifically, in the example shown in FIG. 2, a semiconductor layer 21 of some transistor elements 20 such as the switches and the driving transistor DRT is provided on the under coat layer 111. The transistor element 20 shown in FIG. 2 corresponds to the third switch SW3 in FIG. 1. The semiconductor layer 21 is covered by the gate insulation film 112.

A gate electrode 20G of the transistor element 20 and a gate line not shown are provided on the gate insulation film 112. A source electrode 20S and a drain electrode 20D of the transistor element 20 and a signal lines not shown are disposed on the interlayer insulation film 113.

These source electrode 20S and drain electrode 20D each contact to the semiconductor layer 21 via a contact hole passing through the gate insulation film 112 and the interlayer insulation film 113. These source electrode 20S, drain electrode 20D and the signal line are covered by the protection film 114.

In this embodiment, the organic EL element 40 is provided on the protection film 114. This organic EL element 40 has a structure including a first electrode 60, a second electrode 64 and an organic active layer 62 held therebetween. More detailed structure of the organic EL element 40 is described as follows.

Specifically, the first electrode 60 functions as an anode and is provided on the protection film 114 in an insular shape in each pixel. This first electrode 60 contacts to the drain electrode 20D via a contact hole passing through the protection film 114.

The first electrode 60 may be a laminated structure which includes a reflecting layer made of conductive material such as aluminum (Al) or silver (Ag) and a transparent conductive layer such as indium-tin oxide (ITO) or indium-zinc-oxide (IZO) on the reflecting layer. The first electrode 60 may be also a single layer structure made of a reflecting layer or of a transparent conductive layer. However, in case of top-emission type, it is desirable that the first electrode 60 includes a reflecting layer.

The organic active layer 62 is disposed on the first electrode 60 and includes at least a light-emitting layer. The organic active layer 62 may include layers other than the light-emitting layer. For example, the organic active layer 62 may include a hole injection layer, a hole transporting layer, a blocking layer, an electron transporting layer, an electron injection layer and a buffer layer, or the organic active layer 62 may include a layer in which the functions of these layers are integrated. The light-emitting layer is formed of an organic material and other layers in the organic active layer 62 may be formed of an inorganic material or of an organic material. The light-emitting layer is formed of an organic compound having a light emission function of emitting red, green or blue light. At least a part of the organic active layer 62 is formed of a high polymer material, and the organic active layer 62 can be formed by coating a liquid-phase material by selective coating method such as ink jet method, and then drying the liquid-phase material. The organic active layer 62 also may include a layer made of a low polymer material. In that case, the layer like this can be formed by an evaporation coating method with using an evaporation mask.

The second electrode 64 is disposed on the all organic active layers 62 commonly, and functions as, for example, a cathode. The second electrode 64 may be a laminate structure including a semi-transmissive layer made of mixture of silver (Ag) and magnesium (Mg) and a transparent conductive layer such as indium-tin-oxide (ITO). The second electrode 64 may be also a single layer structure made of a semi-transmissive layer or of a transparent conductive layer. However, in case of top-emission type, it is desirable that the second electrode 64 includes a semi-transmissive layer.

The array substrate 100, in the active area 102, includes partition walls 70 which isolate at least the pixels PX (R, G, B) of neighboring colors. The partition walls 70 are disposed, for example, along the peripheral edges of the first electrodes 60, and are formed in lattice shapes or in stripe shapes in the active area 102. This partition walls 70 make the organic EL elements having different colors partitioned each other. The partition walls 70 are formed, for example, by patterning a resin material. The partition walls 70 are covered by the second electrode 64.

The sealing substrate 200 is disposed so as to oppose to the organic EL elements 40 in the array substrate 100. The array substrate 100 and the sealing substrate 200 are bonded each other by the seal member 300 which is disposed around the active area 102. The seal member 300 is made of frit glass. The frit glass can be melt by heat such as irradiation with a laser, and can bond the array substrate 100 and the sealing substrate 200. That makes an enclosed space between the array substrate 100 and the sealing substrate 200. The organic EL elements 40 are disposed in the enclosed space, and they are sealed.

By the way, in this embodiment, the organic EL display device 1 includes a resin layer 500 disposed between the array substrate 100 and the sealing substrate 200, this resin layer 500 is made of an organic material such as a photosensitive resin including an ultraviolet cure type resin or a heat cure type resin. In case of top-emission type, the resin layer is made of a material being transparent.

The resin layer 500 absorbs the roughness of the surface of the array substrate 100 and is attached to the inner surface of the sealing substrate 200.

In this structure, the gap between the array substrate 100 and the sealing substrate 200 can be even because of the resin layer 500. Moreover, the generation of the moiré stripe caused by the optical interference can be suppressed because the difference between the refraction index of the organic material of the resin layer 500 and one of glass of sealing substrate 200 is small. Thereby, good display quality can be achieved.

Furthermore, because the sealing substrate 200 having flat inner surface can be applicable in this structure, a special process such as etching process to make a concave is not needed and the cost for manufacturing the display device can be reduced. Moreover, even in case that the panel size is large, the distortion of the sealing substrate 200 can be reduced and the mechanical strength can be sufficient.

It is desirable that the array substrate 100 includes a cover film 410 which covers the organic EL elements of the pixels. In this case, the cover film 410 is disposed over the second electrode 64. The cover film 410 is disposed at least over the active area 102 and desirably over the outside the most outer partition wall 70.

The cover film 410 is made of an inorganic material which has lower water permeability than that of the resin layer 500. In case of top-emission type, the cover film 410 is made of a light transparent material. In this embodiment, the cover film 410 is made of one of silicon oxide such as SiO2, silicon nitride such as SiNx, silicon oxide nitride such as SiON and metal oxide such as AlO3.

Preferably, the cover film is formed by some dry forming method such as chemical vapor deposition (CVD) or sputter. The reason why the dry forming method is preferable is that the dry forming method does not provide much damage to the organic EL elements 40 relatively.

The cover film 410 is disposed between the organic EL element 40 and the resin layer 500. Thereby, even if the resin layer 500 includes moisture or the second electrode 64 include some defects such as pin hole, the organic EL element 40 is not deteriorated by the moisture because the organic EL element 40 is covered by the cover film 410. Therefore, the lifetime of the organic EL display device 1 can be increased.

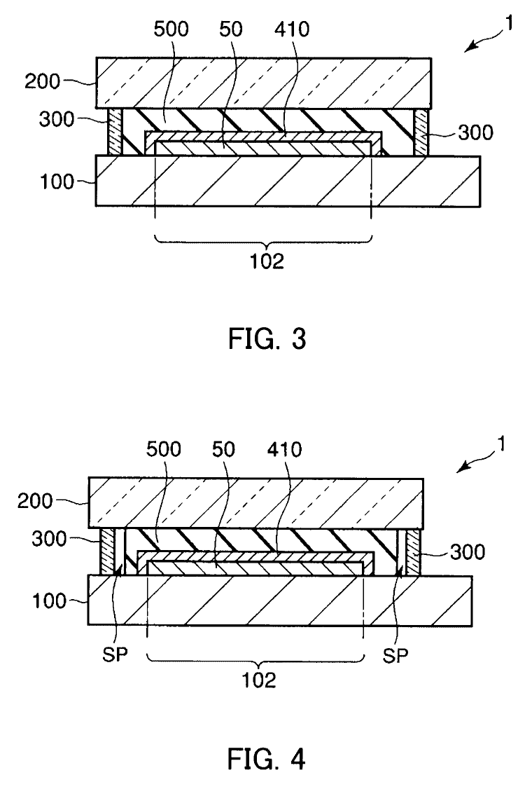

Next, examples of the structure of this embodiment will be described. In addition, in FIGS. 3-5, display element portion 50 including the organic EL elements 40 of all pixels is disposed in the active area 102 and is covered by the cover film 410.

In the example shown in FIG. 3, the resin layer 500 is filled up in the inner portion surrounded by the seal member 300. In other words, the resin layer 500 is disposed in the space enclosed by the array substrate 100, the sealing substrate 200 and the seal member 300 which is frame shape surrounding the active area 102. That is, the resin layer 500 contacts the seal member 300 along whole circumference.

With this example, the display device can have high mechanical strength because there is no airspace between the array substrate 100 and the sealing substrate 200. Moreover, the picture-frame size of the display device can be reduced.

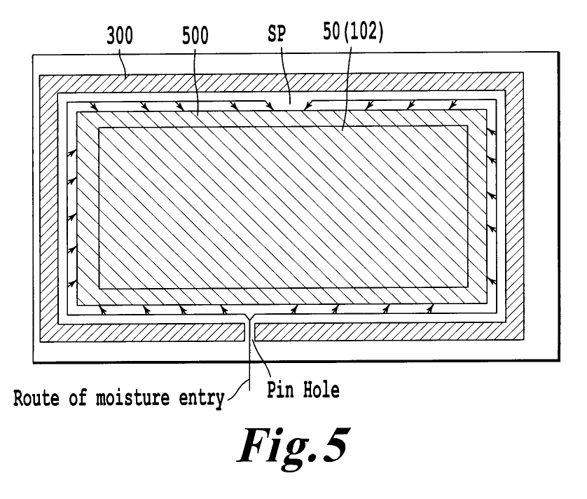

In the example shown in FIGS. 4 and 5, there is a space SP between the seal member 300 and the resin layer 500. The resin layer 500 does not contact the seal member 300 and there is a space SP with an acceptable range about the picture-frame size. Therefore, the space SP has a looped shape surrounding the active area 102. The space SP may be vacuumed or may be filled with inert gas such as nitrogen with non-moisture-containing.

In this example, even if moisture invades into the display device through a minute pin hole in the seal member 300, the moisture disperses into the whole space SP. Therefore, the moisture does not attack a certain pixel near by the pin hole locally and the damage of the pixel can be reduced.

Moreover, with this example, a laser which is irradiated in order to melt the seal member 300 made of frit glass does not damage the resin layer 500 because of the space SP. Therefore, the manufacturing process margin can be widened.

Next, the results of verification of the organic EL display device according to this embodiment will be described.

Firstly, three sheets of glass substrates (A, B and C) to be plural array substrates 100 are prepared. The size of each sheet is 400 millimeters by 500 millimeters (400 mm×500 mm) which can includes twenty four array substrates being 3.5 inches in the diagonal dimension of the active area 102. The pixel circuit 10 is formed at each pixel in each active area 102, and then, the pixel circuit 10 is covered by the protection film 114. Thereby, the wiring substrate 120 is formed. The transistor element such as the switch or the driving transistor (DRT) which comprises the pixel circuit 10 is low-temperature polycrystalline silicon TFT which includes a polycrystalline silicon film as a semiconductor layer.

After then, the first electrode 60 is formed on the protection film 114. The protection film 114 includes a reflecting layer such as aluminum (Al) and a transparent conductive layer such as indium-tin-oxide (ITO) on the reflecting layer. The first electrode 60 is connected to the transistor element 20 via a contact hole passing through the protection film 114.

Next, the partition wall 70 is formed so as to surround each first electrode 60 on the protection film 114. The pitch of the partition wall is 73 microns by 219 microns, and the area size of the inner portion of the partition wall 70, which can work for displaying, is 40 microns by 140 microns.

And then, the substrates above described are set in an organic EL film forming machine which is a resistive heating way. An α-NPD, as a hole transporting layer, is formed to 200 nm thick on the substrates. Next, An Alq3, as both of a light-emitting layer and an electron transporting layer, is formed to 50 nm thick on the hole transporting layer. Further, a magnesium (Mg) and silver (Ag), as both of a electron injection layer and a buffer layer (semi-transmissive layer), are formed to 2 nm thick thereon. Next, an indium-tin-oxide (ITO) is formed to 100 nm thick by plasma CVD method thereon.

On the other hand, other three sheets of glass substrate (a, b and c) to be plural sealing substrates 200 are prepared. The size of each sheet is 400 millimeters by 500 millimeters (400 mm×500 mm). The each sheet has plural seal patterns of frit glass each of which is disposed so as to surround the active area 102 of array substrate 100. That is, there are 24 seal patterns in each sheet.

In each sheet, the width of the seal is 1 mm for 12 seal patterns (a-1, b-1 and c-1) and the width of the seal is 0.4 mm for the other 12 seal patterns (a-2, b-2 and c-2).

In the glass substrate b, a resin film is attached to the substrate in the area encircled by each seal pattern so that the edge of the resin film is 0.2 mm˜0.3 mm apart from the seal.

In the glass substrate c, a resin film is attached to the substrate in the area encircled by each seal pattern so that the edge of the resin film is 0.7˜0.8 mm apart from the seal.

In the glass substrate a, there is no resin film on the substrate.

Next, these glass substrates a, b and c are attached to the glass substrates A, B and C, respectively. And then, the frit glass as the seal is welded and thereby the both substrates are bonded. Moreover, these substrates are disposed in a high-temperature chamber and the resin film is cured. Thereby, pair of substrates Aa, Bb and Cc can be prepared.

After dividing these pair of substrates into cells, peripheral circuits such as a signal supply are implemented to each cell. Thereby, the organic EL display device is completed.

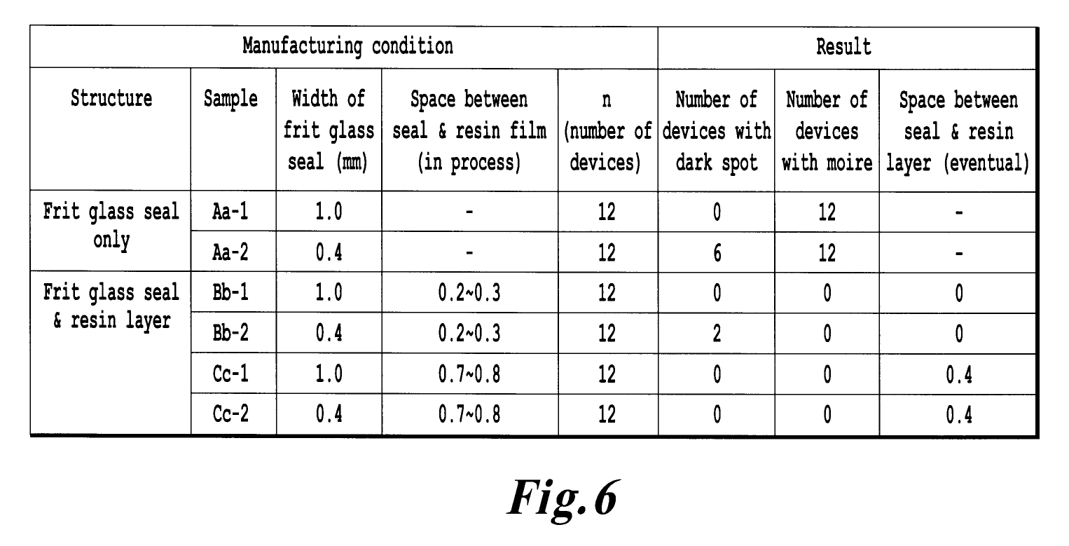

Next, the organic EL display device is set in a high-temperature and high-humidity chamber (85° C./85% RH). After 500 hours from setting in the chamber, we noted the result of the test about whether there is a dark spot or not and whether there is a moiré stripe or not in each organic EL display device. And we measured the space width between the seal member 300 and the resin layer 500. These results are shown in FIG. 6.

In the structures having the frit glass as the seal member 300 without the resin layer 500 (Aa-1 and Aa-2), there are some moiré stripes in all 24 devices. On the other hand, in the structures having the frit glass and the resin layer 500 (Bb-1, Bb-2, Cc-1 and Cc-2), there is no moiré strip in every device despite the difference in the width of the seal.

By this result, we find out that the combination of the frit glass as the seal member and the resin layer can reduce the generating the moiré stripes and can achieve a good display quality.

Moreover, in the structure having the frit glass and the resin layer 500, we find out that the generation of a dark spot is reduced even if the seal member has narrow width which tends to get a hole in the seal member.

As for the devices having 0.4 mm in seal width, in 12 devices of Aa-2 which have the frit glass without the resin layer, there are 6 devices having some dark spots. On the other hand, in 12 devices of Bb-2 which have the frit glass and the resin layer, there are only 2 devices having some dark spots. Moreover, in 12 devices of Cc-2 which also have the frit glass and the resin layer, there is no device having a dark spots.

Thereby, we find out that the deterioration of the organic EL element can be restrained by the resin layer covering over the active area even if the moisture invade into the inner portion of the device via a hole in the seal member.

As for the devices having the frit glass and the resin layer, we find out that the devices of Cc-1 and Cc-2 which have a space between the frit glass and the resin layer are better for the restraining the dark spots than the devices of Bb-1 and Bb-2 which do not have a space between the frit glass and the resin layer.

As for the devices having 0.4 mm in seal width, in 12 devices of Bb-2 which do not have a space between the frit glass and the resin layer, there are 2 devices having some dark spots. On the other hand, in 12 devices of Cc-2 which have a space between the frit glass and the resin layer, there is no device having a dark spot. In the structure having the space, even if the moisture invade into the inner portion of the device, the moisture can be dispersed throughout the space, thereby, the moisture do not attack only a certain pixel near the hole which the moisture passes through. Therefore, the structure having the space is better able to restrain the generation of dark spot.

In the above inspection, the devices having narrow seal width (0.4 mm) are used as a sample tending to get a hole in the seal member. The result of this inspection shows that the reducing of the process yield can be restrained even if the frit glass gets a pin hole because of the unsteadiness of the manufacturing process.

As described above, according to the organic EL display device of the present embodiment, the generation of the moiré stripe can be suppressed, good display quality can be achieved, the thickness can be thinner and the display size can be larger with maintenance of the necessary mechanical strength.

The present invention is not limited directly to the above-described embodiments. In practice, the structural elements can be modified without departing from the spirit of the invention. Various inventions can be made by properly combining the structural elements disclosed in the embodiments. For example, some structural elements may be omitted from all the structural elements disclosed in the embodiments. Furthermore, structural elements in different embodiments may properly be combined.

What is claimed is:

1. A display device including an active area having a plurality of pixels comprising:
an array substrate including a plurality of display elements disposed at said pixels respectively;
a sealing substrate disposed to be opposed to said array substrate; and
a seal member disposed between said array substrate and said sealing substrate and encircling said active area;
wherein said seal member is made of frit glass, and a resin layer is disposed between said array substrate and said sealing substrate in said active area.

2. The display device according to claim 1, further comprising a space disposed between said seal member and an edge of said resin layer.

3. The display device according to claim 2, wherein said space has a looped shape surrounding said active area.

4. The display device according to claim 1, further comprising a cover film made of an inorganic material covering said active area on said array substrate.

5. The display device according to claim 1, wherein a light generated by said display element goes through said sealing substrate.

6. The display device according to claim 5, further comprising a cover film made of an inorganic and transparent material covering said active area on said array substrate.
